(19) United States
(12) Patent Application Publication
(10) Pub. No.: US 2012/0025293 A1
(43) Pub. Date: Feb. 2, 2012

(54) SEMICONDUCTOR MEMORY DEVICE HAVING A FLOATING GATE AND A CONTROL GATE AND METHOD OF MANUFACTURING THE SAME

(75) Inventors: Wataru Sakamoto, Mie-ken (JP); Fumitaka Arai, Kanagawa-ken (JP)

(73) Assignee: Kabushiki Kaisha Toshiba, Tokyo (JP)

(21) Appl. No.: 13/194,131

(22) Filed: Jul. 29, 2011

(30) Foreign Application Priority Data
Jul. 30, 2010 (JP) 2010-172739

(51) Int. Cl. H01L 29/788; H01L 21/336

(52) U.S. Cl. 257/316; 438/264; 257/E29.3; 257/E21.422

(57) ABSTRACT

According to one embodiment, a semiconductor memory device having a memory cells and word lines is provided. The memory cells are formed in a semiconductor layer and arranged in matrix. Each of the memory cells has a floating gate and a control gate. Each plurality of the memory cells is connected in series in a row direction. Each of the word lines is connected to each plurality of the control gates in a column direction. First and second intervals are provided for the memory cells alternately in the column direction. The second interval is larger than the first interval.

### CROSS-REFERENCE TO RELATED APPLICATION(S)

This application is based upon and claims the benefit of priority from the prior Japanese Patent Application No. 2010-172739, filed on Jul. 30, 2010, the entire contents of which are incorporated herein by reference.

### FIELD

Embodiments described herein relate generally to a semiconductor memory device and to a method of manufacturing the semiconductor memory device.

### BACKGROUND

A NAND flash memory is known as a semiconductor memory device. The NAND flash memory is provided with nonvolatile memory elements having a floating gate and a control gate respectively. As to the NAND flash memory, requirement of writing and reading speed-up is increasing. In order to meet the requirement, the voltage ratio (coupling ratio) of the following two voltages needs to be raised. One of the voltages is a voltage which is applied between the control gate electrode and the floating gate electrode. The other of the voltages is a voltage which is applied between the floating gate electrode and a channel region of a semiconductor substrate.

For the purpose of raising the coupling ratio, the height of an element isolation region is set to be lower than that of an upper surface of a floating gate. Consequently, the contact area between an inter-gate insulating film and the floating gate can be increased and a control gate electrode can be embedded between floating gates.

### BRIEF DESCRIPTION OF THE DRAWINGS

FIG. 1 is a functional block diagram of a NAND flash memory according to a first embodiment.

FIG. 2 is a circuitry diagram of a portion of a memory cell array shown in FIG. 1.

FIG. 3 is a schematic and enlarged view of a section of the memory cell array which is taken along an A-A line of FIG. 2.

FIG. 4 is an enlarged view of a portion of a section of the memory cell array which is taken along a B-B line of FIG. 2.

FIG. 5 is an enlarged plane view of a portion C of the memory cell array which is shown in FIG. 2.

FIGS. 6A-6L show respective sections of a semiconductor substrate which are obtained in steps of a method of manufacturing the NAND flash memory according to the first embodiment.

FIG. 7 shows a capacitance network of the NAND flash memory according to the first embodiment.

FIG. 8 is a sectional view of the semiconductor substrate to show a displacement of contacts.

FIGS. 9A-9G show respective sections of a semiconductor substrate which are obtained in steps of a method of manufacturing the NAND flash memory according to a second embodiment.

FIG. 10 shows a portion of a section of a NAND flash memory according to a third embodiment.

FIG. 11 shows a portion of a section of a NAND flash memory according to a fourth embodiment.

### DETAILED DESCRIPTION

According to one embodiment, a semiconductor memory device having a memory cells and word lines is provided. The memory cells are formed in a semiconductor layer and arranged in matrix. Each of the memory cells has a floating gate and a control gate. Each plurality of the memory cells is connected in series in a row direction. Each of the word lines is connected to each plurality of the control gates in a column direction. First and second intervals are provided for the memory cells alternately in the column direction. The second interval is larger than the first interval.

Hereinafter, further embodiments will be described with reference to the drawings. In the drawings, the same reference numerals denote the same or similar portions respectively.

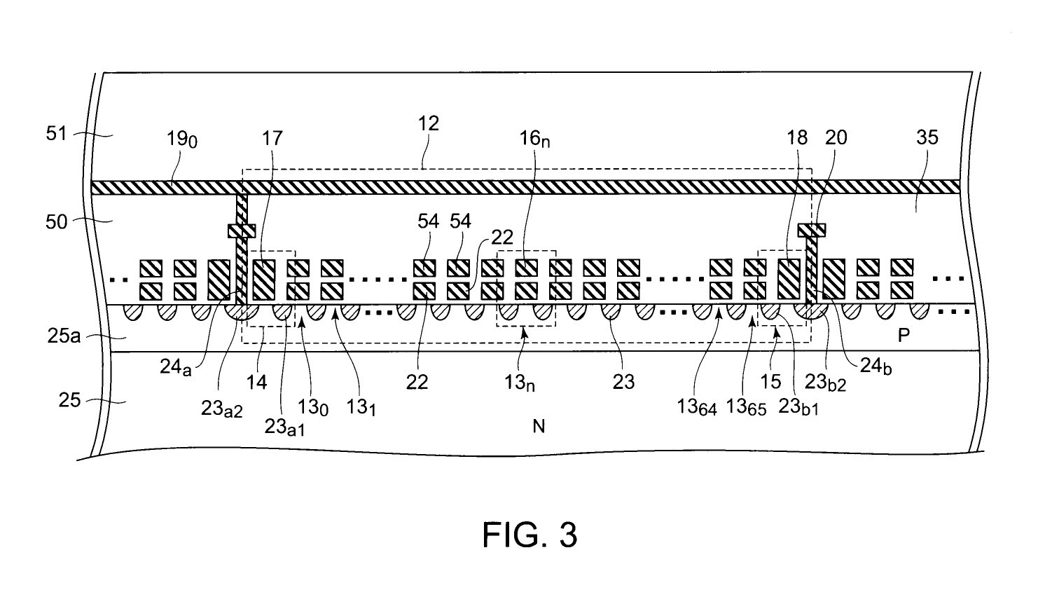

For explanatory convenience, in the description of the embodiments, directions i.e. relative positional relationships for indicating up and down, right and left, high and low, or deep and shallow are mentioned as those determined according to a back surface side of a semiconductor substrate. Accordingly, in some parts of the description, the directions may be shown as different from those determined according to a gravity direction. In FIGS. 3-11, portions such as a front or back surface of a semiconductor memory device which are not important for explaining the embodiments may be omitted.

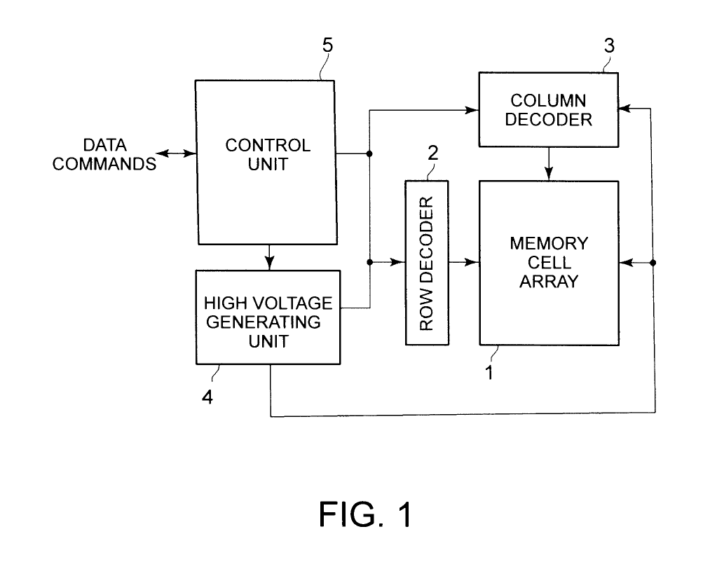

A NAND flash memory according to a first embodiment will be described with reference to FIG. 1.

FIG. 1 is a functional block diagram of the NAND flash memory. In a memory cell array 1 shown in FIG. 1, a plurality of memory cells is arranged in matrix.

A row decoder 2 is provided to select and drive word lines and selection gate lines respectively provided in the memory cell array 1. A column decoder 3 is provided to select bit lines provided in the memory cell array 1.

A high voltage generating unit 4 is provided to boost a power supply voltage supplied from outside. The high voltage generating unit 4 supplies a boosted voltage to the memory cells of the memory cell array 1, the row decoder 2 and the column decoder 3, when data stored in each memory cell is read, data is written into each memory cell, or data stored in each memory cell is erased. “High voltage” means a voltage which is larger than a supply voltage provided from outside and which is necessary for reading, writing and erasing. A control unit 5 controls the row decoder 2, the column decoder 3 and the high voltage generating unit 4, and has a function to control the memory cell array 1 through these decoders and the high voltage generating unit.

Further, the control unit 5 has a function to perform receiving commands from the exterior of the NAND flash memory and to perform outputting data to the exterior. The memory cell array 1, the row decoder 2, the column decoder 3, the high voltage generating unit 4 and the control unit 5 are formed on a semiconductor substrate 100 described below.

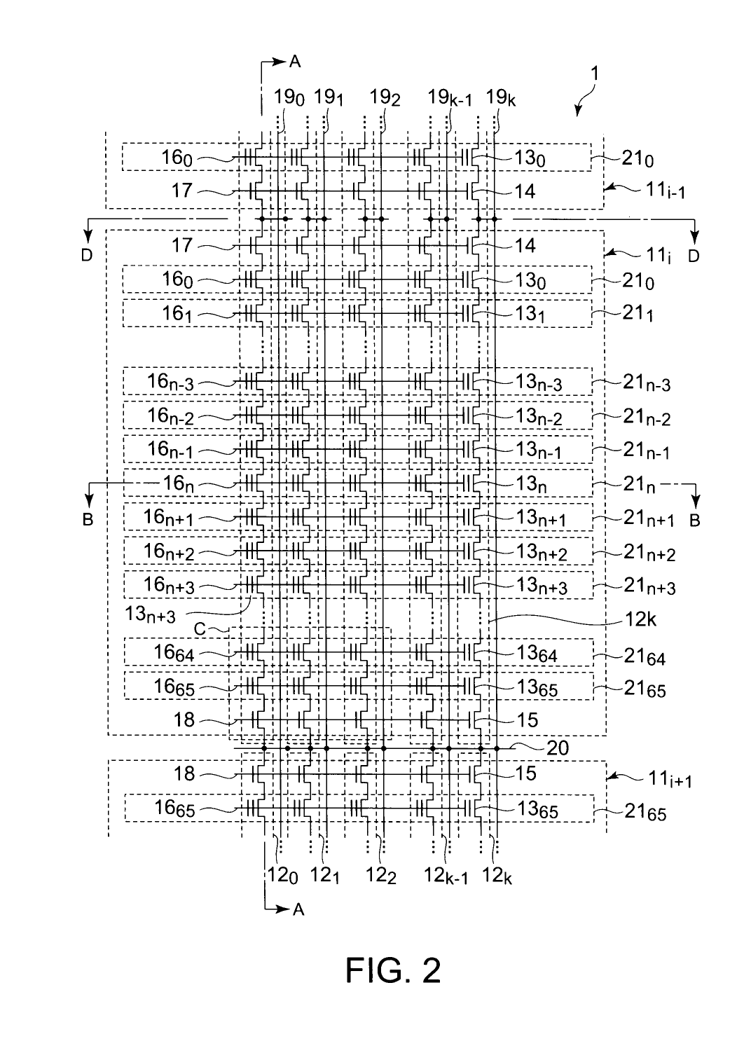

FIG. 2 shows a portion of circuit configuration of the memory cell array 1 formed on the semiconductor substrate. The memory cell array 1 has a plurality of blocks. FIG. 2 shows a block 11, and portions of blocks 11ᵢ₋₁ and 11ᵢ₊₁. “i” represents an arbitrary integer.

Each of the blocks 11₀-11ₓ is provided with a plurality of NAND memory cell units. In FIG. 2, the NAND memory cell units 12₀-12ₖ are provided in the block 11ᵢ₊₁. “k” is an arbitrary integer and is “4224”, for example.

Each of the NAND memory cell units is provided with a plurality of memory cells 13₀-13₆₅. These memory cells are arranged to store data. FIG. 2 shows that the memory cells 13₀-13₆₅ are arranged in the NAND memory cell unit 12ₖ. Each of the memory cells 13₀-13₆₅ is composed of a nonvolatile memory transistor having a floating gate and a control gate.

The memory cells 13₀-13₆₅ are connected in series. Each source of the memory cells is connected with a drain of adjacent one of the memory cells. First one to third ones of the memory cells 13₀-13₆₅ connected in series and arranged from both ends of the NAND memory cell units 12ₖ may be used as dummy cells. The dummy cells store invalid data respectively. For example, the memory cells 13₀ and 13₆₅ of the first row from the both ends may be used as the dummy cells respectively. Or the memory cells 13₀-13₂ and 13₆₃-13₆₅ of the first to third row from the both ends may be used as dummy cells respectively.

Each of the NAND memory cell units 12₀-12ₖ is further provided with selection gate transistors 14 and 15. The selection gate transistors 14 are connected in series with the drains of the memory cells 13₀ connected in series with the others of the memory cells 13₀-13₆₅, respectively. The selection gate transistors 15 are connected in series with the sources of the memory cells 13₆₅ connected in series with the others of the memory cells 13₀-13₆₅, respectively. The NAND memory cell units 12₀-12ₖ are selected by the selection gate transistors 14, 15 respectively.

The control gates of the nonvolatile memory transistors of the ones of the memory cells 13₀-13₆₅ which are arranged in each column are connected commonly to each of a plurality of word lines 16₀-16₆₅. Specifically, among the memory cells 13₀-13₆₅ disposed in matrix, the memory cells of the NAND memory cell units 12₀-12ₖ which are arranged in a column direction perpendicular to a series-connection direction of the memory cells, i.e. a row direction memory cell are connected commonly to each of a plurality of the word lines 16₀-16₆₅. The portions of the word lines 16₀-16₆₅ corresponding to the positions of the memory cells functions as control gates.

Accordingly, when the memory cells 13₀-13₆₅ are connected in series in a block 11ᵢ as mentioned above, each 66 of the memory cells arranged in the column direction is connected commonly to each of the word lines 16₀-16₆₅.

In each of page areas 21₀-21₆₅, ones of the memory cells connected to each of the word lines 16₀-16₆₅ are arranged respectively. Each of page areas 21₀-21₆₅ includes the memory cells of the number of the NAND memory cell units in each block (“k+1” in FIG. 2). For example, in a case of k=4224, 4096 memory cells may be used for a storage area, and 128 memory cells may be used for a redundancy area and another area.

Drains of the nonvolatile memory transistors constituting the memory cells 13₀-13₆₅ are connected to bit lines 19₀-19ₖ respectively. The gates of the selection gate transistors 14 arranged in each column are commonly connected to each selection gate line 17. Each drain of the selection gate transistors 14 is connected to each of the bit lines 19₀-19ₖ.

The gates of the selection gate transistors 15 arranged in each column are commonly connected to each selection gate lines 18. The sources of the selection gate transistors 15 arranged in each column are commonly connected to each source line 20. The source lines 20 are shared by ones of the blocks which adjoin in the column direction.

FIG. 3 is a schematic view of a structure of a section of the memory cell array 1 formed on the semiconductor substrate. The section is taken along a line A-A shown in FIG. 2.

The memory cells 13₀-13₆₅ have a stacked gate structure where a floating gate 22 and a portion of word line 16n which functions as a control gate are laminated via an insulating film on a P type semiconductor layer 25a formed in a N type semiconductor substrate 25.

The memory cells 13₀-13₆₅ are connected in series in the column direction. For example, a source and a drain of a nonvolatile memory transistor constituting one of the memory cells 13₀ are respectively connected to a drain of an adjacent nonvolatile memory transistor constituting one of the memory cells 13₁ and a source 23ₐ₁ of one of the selection gate transistors 14. Further, a drain and a source of a nonvolatile memory transistor constituting one of the memory cells 13₆₅ are respectively connected to a source of an adjacent nonvolatile memory transistor constituting one of the memory cells 13₆₄ and a drain 23_{b1} of one of the selection gate transistors 14.

A drain 23ₐ₂ of the one of the selection gate transistors 14 is connected to a bit line 19₀ via a contact plug 24ₐ. A source 23_{b2} of the one of the selection gate transistors 15 is connected to a source line 20 via a contact plug 24_{b}.

The sources and drains of the nonvolatile memory transistors constituting memory cells 13₀ including the source 23ₐ₁, 23_{b2}, and the drain 23ₐ₂, 23_{b1}, can be formed by implanting ions into the P type layer 25a formed in the semiconductor substrate 25. The floating gate 22, a portion of the word line 16, which functions as a control gate, and the contact plug 24ₐ, 24_{b} are embedded in an insulating layer 50. The bit lines 19₀-19ₖ are covered with the insulating film 51.

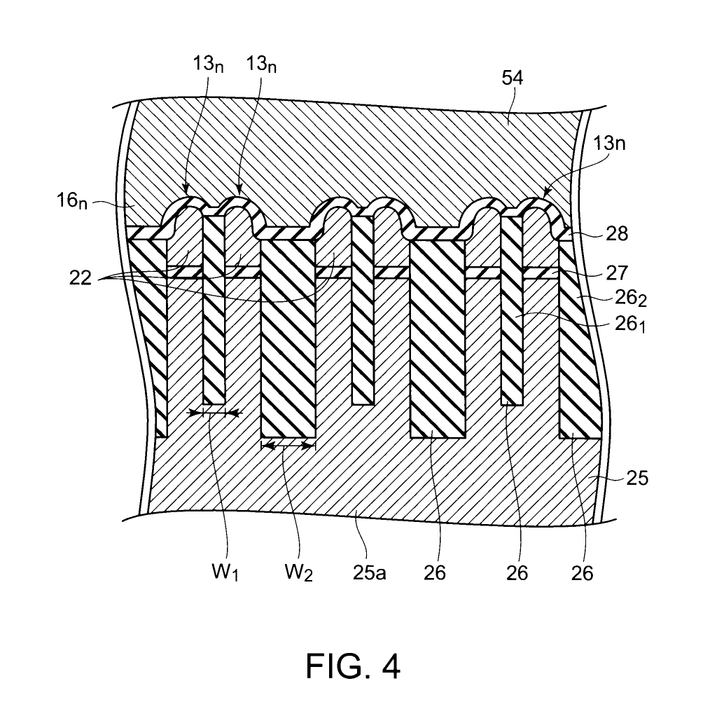

FIG. 4 shows an enlarged and schematic view of a portion of a section of the memory cell array shown in FIG. 2. The section is taken along a line B-B shown in FIG. 2. FIG. 4 shows six memory cells 13ₙ of FIG. 2.

The memory cells 13ₙ are electrically separated by element isolation insulating layers 26 including first and second element isolation layers 26₁, 26₂ respectively. Specifically, in the embodiment, the memory cells 13ₙ are electrically separated using an STI structure. A silicon oxide film, which is deposited in the interiors of trenches formed in the semiconductor substrate 25 (the P type semiconductor layer 25a), can be used for the element isolation insulating layers 26.

The widths of the first and second element isolation layers 26₁, 26₂ are different in the column direction. The first and second element isolation layers 26₁, 26₂ are arranged alternately and repeatedly in the column direction. The width of the second element isolation layer 26₂ is larger in the column direction than that of the first element isolation layer 26₁. The memory cells 13ₙ are formed so that a first interval W₁ and a second interval W₂ may be provided alternately and repeatedly among the memory cells. The first interval W₁ corresponds to the width of the first element isolation layer 26₁. The second interval W₂ corresponds to the width of the second element isolation layer 26.

The height of the first element isolation layer 26₁ is larger than that of the second element isolation layer 26₂. The heights of the first element isolation layer 26₁ and the second element isolation layer 26₂ are larger than that of an upper surface of a tunnel insulating film 27.

The height of the second element isolation layer 26₂ is smaller than that of a portion of an upper surface of the floating gate 22 which has a largest height. Accordingly, the portions 54 shown in FIG. 3 which function as control gates, i.e. portions of the word line 16ₙ is filled in a space between the floating gates 22 corresponding to the width of the second element isolation layer 26₂. The word line 16ₙ (the control gates) is formed via an inter-gate insulating film 28 on the first and second element isolation layers 26₁, 26₂ and the floating gate 22.

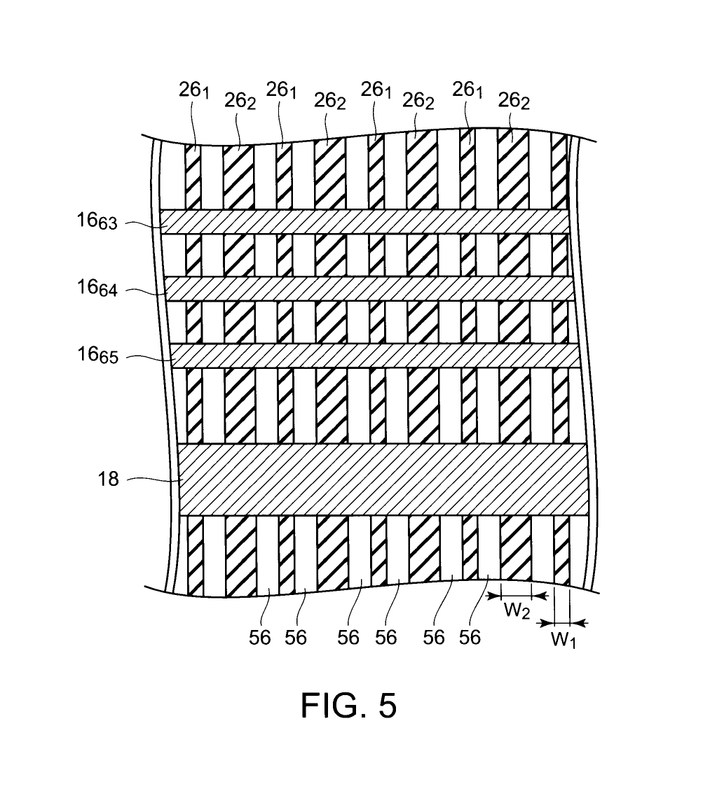

FIG. 5 shows a positional relationship among the word lines 16₆₃-16₆₅, the selection gate lines 18, and active areas 56 in a portion C of the memory cell array 1 surrounded by a dotted line in FIG. 2. In each of the active areas 56, a source, a drain and a channel region are formed. FIG. 5 shows the active areas 56, the word line 16₆₃-16₆₅, one of the selection gate lines 18 and the first and second element isolation layers 26₁, 26₂, and the other configurations are omitted to be shown, for explanatory convenience.

Each of the active areas 56 is formed between each of the first element isolation layers 26₁ and each of the second element isolation layers 26₂. The active areas 26 are formed so that the first and the second intervals W₁, W₂ may be provided alternately and repeatedly among the active areas. Accordingly, the active areas of the selection gate transistors shown in FIGS. 2, 3 are formed so that the first and the second intervals W₂ may be provided alternately and repeatedly among the active areas.

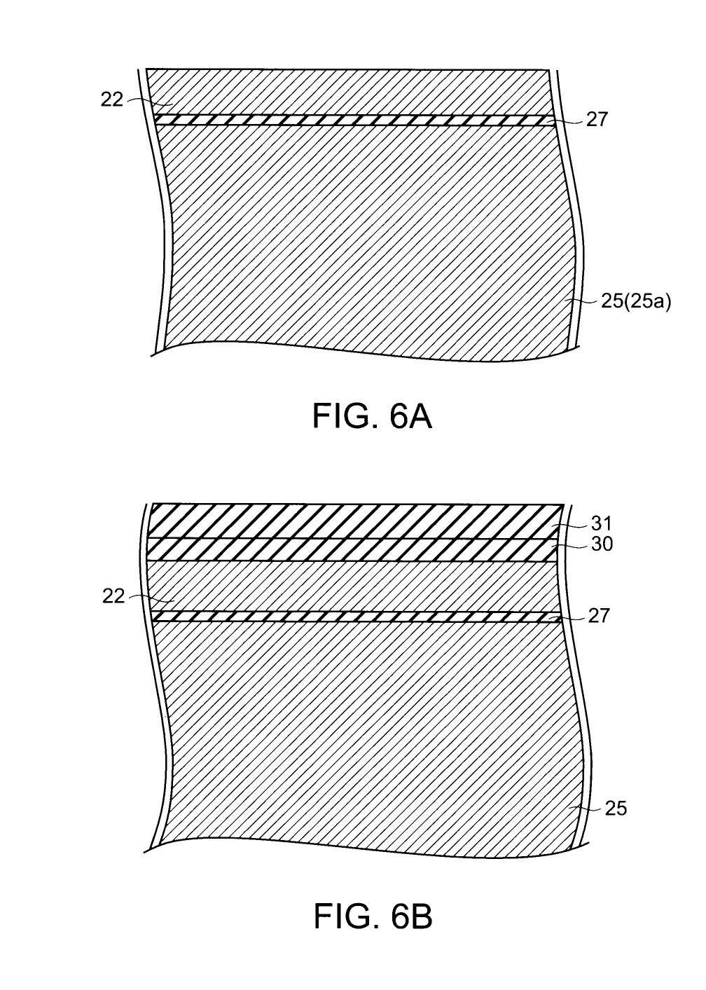

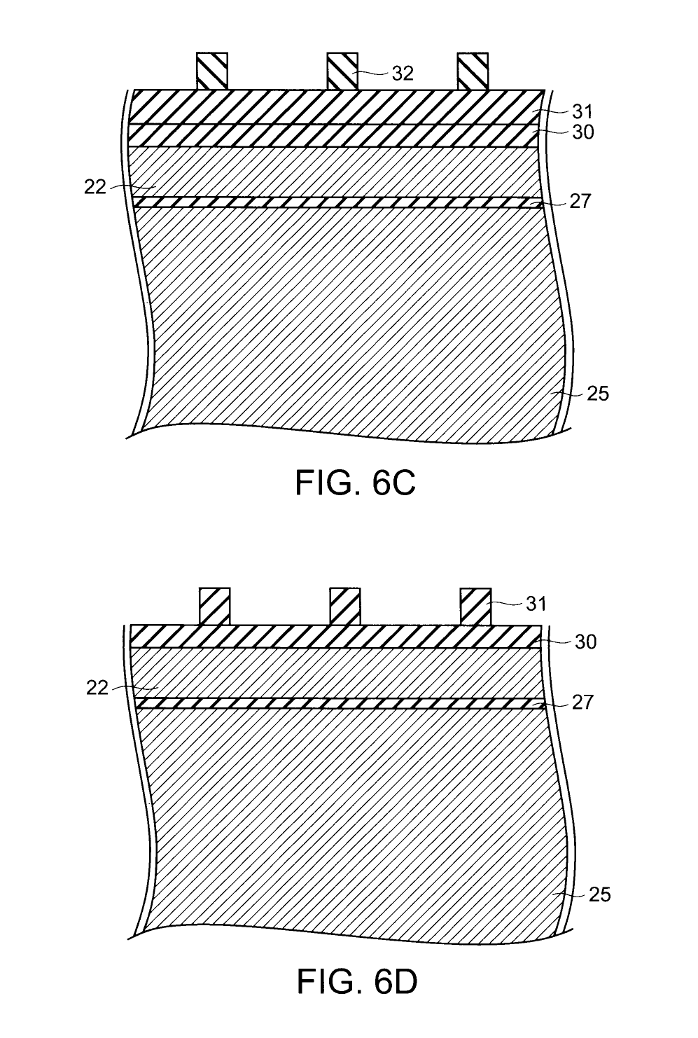

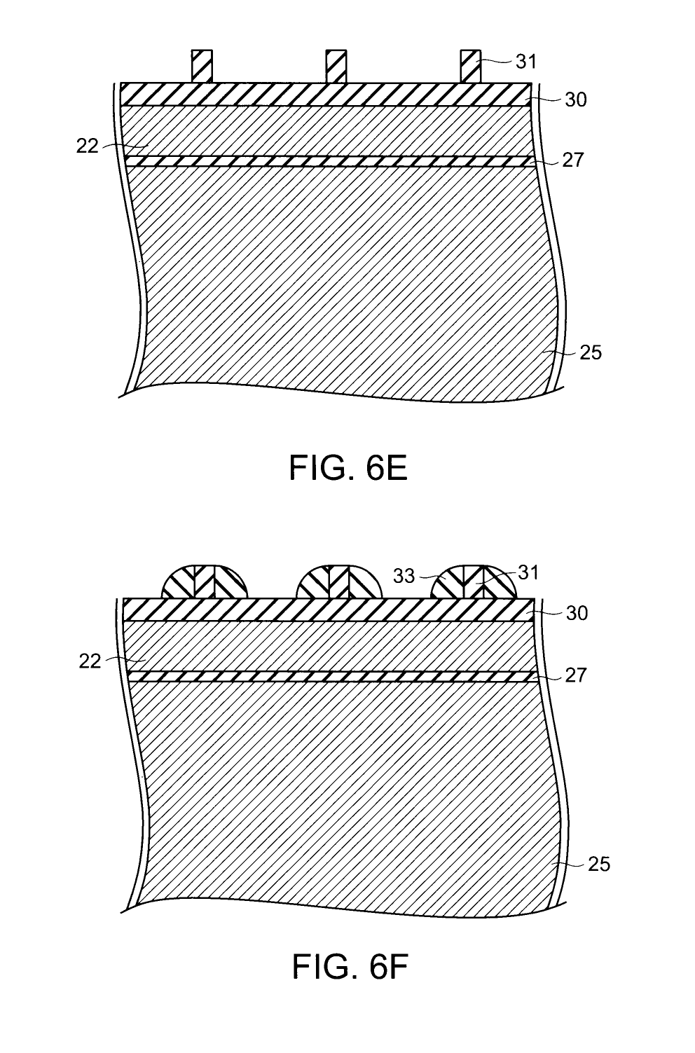

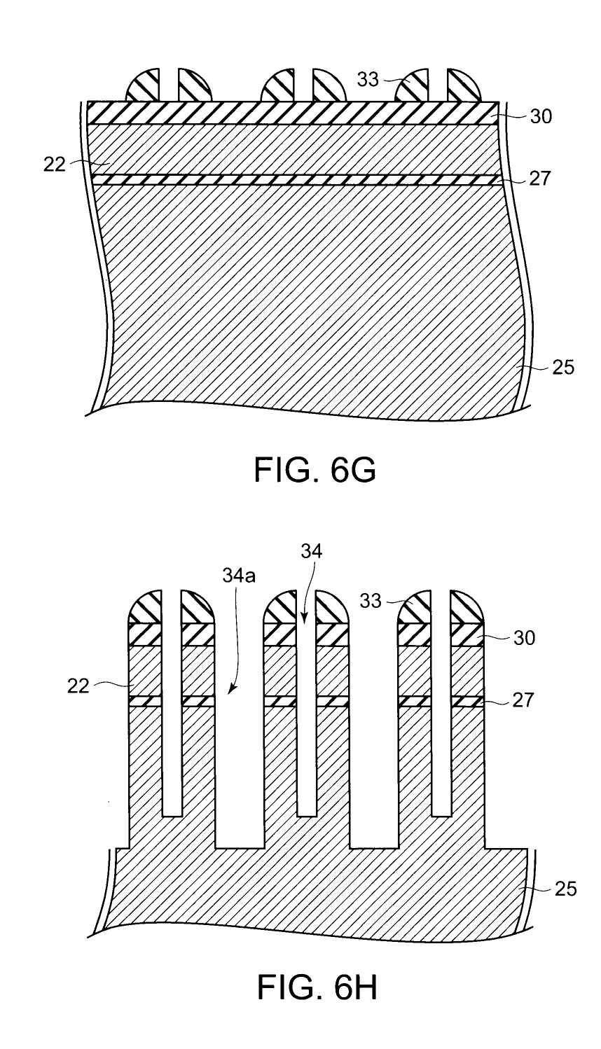

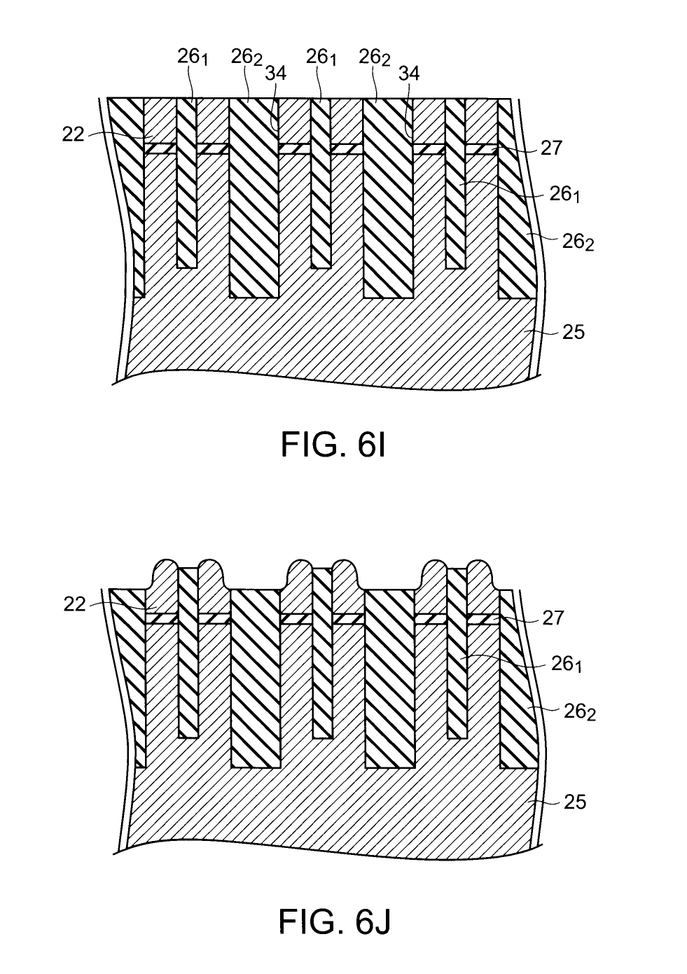

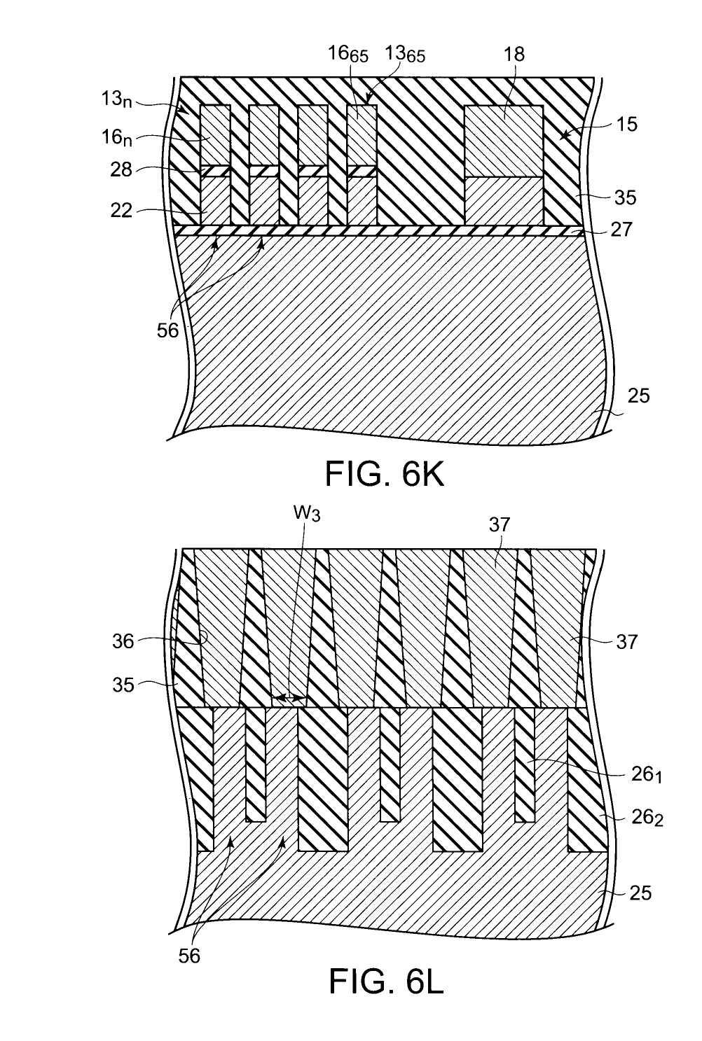

FIGS. 6A-6L show enlarged sectional views of a semiconductor substrate in respective steps of an example of a method of manufacturing the NAND flash memory according to the first embodiment. Each of FIGS. 6A-6J corresponds to a portion of the B-B section shown in FIG. 2. FIG. 6K corresponds to a portion of the A-A section shown in FIG. 2. FIG. 6L corresponds to a portion of a section taken along a line D-D shown in FIG. 2.

As shown in FIG. 6A, a tunnel insulating film 27 and a floating gate layer 22 are formed in the order on a P type semiconductor layer 25a of a semiconductor substrate 25.

A substrate composed of a semiconductor material such as silicon, or a substrate having a semiconductor region formed in the surface area, such as a SOI wafer, may be used as the semiconductor substrate 25. A silicon oxide film formed by a thermal oxidation process, a plasma oxidation process or a CVD process may be used as the tunnel insulating film 27. A poly-silicon film formed by a CVD process, for example, may be used as the floating gate layer 22.

Then, a mask material is formed to provide the element isolation insulating layers 26 shown in FIG. 4. In order to form the mask material, a method of forming a mask material with a width equal to or smaller than that limited with lithography. The method may be, for example, a so-called “Double Patterning” which uses a side wall transfer method.

As shown in FIG. 6B, a mask material 30 and a hard mask material 31 are formed on the floating gate layer 22. The mask material 30 and the hard mask material 31 are used to form the first element isolation layers 26₁ shown in FIG. 4. A silicon nitride film or a silicon oxide film can be used as the mask material 30. The silicon nitride film or the silicon oxide film may be formed using a CVD process, for example. A silicon oxide film, a silicon nitride film or an amorphous silicon film can be used as the hard mask material 31. These films may be formed using a CVD process, for example.

As shown in FIG. 6C, a resist pattern 32 is formed to pattern the hard mask material 31. The resist pattern 32 can be formed using a photolithographic method. The pitch of the resist pattern 32 is double as large as that of the memory cells 13ₙ. The double pitch is a total length of the first interval W₁ and the second interval W₂.

As shown in FIG. 6D, the hard mask material 31 is etched by using the resist pattern 32 as a mask, and then the resist pattern 32 is removed. The etching of the hard mask material 31 can be performed using an anisotropic etching such as an RIE.

As shown in FIG. 6E, slimming of the etched hard mask material 31 is carried out. The width of the hard mask material 31 after the slimming corresponds to the width of the element isolation layers 26₁, and is a width of the first interval W₁ after correction of errors such as an etching conversion difference caused by manufacturing processes. One of the errors is an etching conversion difference, for example. Specifically, the width of the hard mask material 31 after the slimming may be 25% or less of the width of the resist pattern 32, for example.

As shown in FIG. 6F, a side wall film 33 is formed on a side surface of the hard mask material 31. The side wall material 33 functions as a mask at the time of forming the element isolation layers 26₁, 26₂. In order to form the side wall film 33, a side wall material is formed to cover the floating gate layer 22, the mask material 30 and the hard mask material 31 as a whole after the slimming of the hard mask material 31. After forming the side wall material, the side wall film 33 is formed using the following etching process, for example.

A silicon nitride film, a silicon oxide film, or an amorphous silicon film respectively formed by CVD can be employed for the side wall film 33. Such a film has a material characteristic which indicates a sufficient processing selection ratio at the time of etching the hard mask material 31. An etching process such as RIE which leaves a portion of the side wall material on the hard mask material 31 may be used for etching the side wall material. The interval between portions of the hard mask material 31 after the etching corresponds to the width of the element isolation layer 26₂. The interval exists on the opposite side of the hard mask material 31. The interval is a width of the second interval W2 after correction of errors such as an etching conversion difference caused by manufacturing processes.

Then, as shown in FIG. 6G, the side wall film 33 is left and the hard mask material 31 is removed. A wet etching can be used to remove the hard mask material 31.

There may be a case where removal of the hard mask material 31 is not necessary for peripheral regions other than the region to form the memory cell array 1, for example, regions to form the row and the column decoders 2, 3, the high voltage generating unit 4, and the control unit 5. In this case, a photoresist mask can be formed in the peripheral regions by a photolithography before removal of the hard mask material 31 according to necessity.

Then, as shown in FIG. 6H, the mask material 30, the floating gate layer 22, the tunnel insulating film 27 and the semiconductor substrate 25 are etched in the order using the side wall film 33 as a mask so that trenches 34, 34a are formed. For the etching, an anisotropic etching, for example, RIE can be used.

The depths of the trenches 34, 34a depend on the widths of the trenches. The trenches 34 corresponding to narrower intervals provided between portions of the side wall film 33 are formed shallowly by the etching. On the other hand, the trenches 34a corresponding to wider intervals provided between portions of the side wall film 33 are formed deeply by the etching. These are caused by loading effect during etching.

As shown in FIG. 6I, element isolation layers 26₁, 26₂ are filled in the trenches 34 and 34a, respectively. In order to fill the element isolation layers 26₁, 26₂, the side wall film 33 and the mask material 30 are removed in advance, using an etching process such as a wet etching.

After removal of the side wall film 33 and the mask material 30, an insulating film such as a silicon oxide film is deposited or applied to fill the trenches 34, 34a. For the deposition or application, CVD or SOG can be used. After filling the insulating film, flattening is performed using CMP, for example, and element isolation layers 26₁ and 26₂ are formed.

As shown in FIG. 6J, the element isolation layers 26₁, 26₂ are etched until the heights of the layers become lower than the floating gate layer 22. The heights of the element isolation layer 26₁, 26₂ correspond to the widths of the element isolation layers 26₁, 26₂ so that the heights of the element isolation layers 26₂ becomes lower than those of the element isolation layers 26₁ having narrower widths. These are caused by the loading effect described above during etching.

In the case, etching of exposed portions of the floating gate layer 22 which project from the element isolation layer 26₁, 26₂ progresses. As a result, the exposed portions of the floating gate layer 22 becomes thin, and the corner portions becomes round.

Then, as shown in FIG. 4, an inter-gate insulating film 28 and an electrically conductive film to form word lines including the word lines 16, (control gates) are formed, after etching the element isolation layers 26₁, 26₂. For the inter-gate insulating film 28, a silicon oxide film or a silicon nitride film respectively formed using CVD for example, an insulating film having a higher dielectric constant such as an aluminum oxide, or a laminated film of a silicon oxide film and a silicon nitride film can be used. For the electrically conductive film, a polysilicon film formed using CVD for example can be used.

As shown in FIG. 6K which shows a portion of the A-A section of FIG. 2, the electrically conductive film, the gate insulating film 28, and the floating gate layer 22 are patterned perpendicularly to the active areas 56 so that the word lines 16₀, . . . , 16ₙ, . . . , 16₆₅ are formed. After forming the word lines, N type impurities are introduced into the semiconductor substrate 25 i.e. the P type semiconductor region by ion implantation so that sources and drains are formed. The sources and drains may be formed in a previous step. An interlayer insulating film 35 is formed so as to cover the entire surface including word lines 16₀, . . . , 16ₙ, . . . , 16₆₅. For the interlayer insulating film 35, a silicon oxide film formed using CVD may be used.

Then, as shown in FIG. 6L showing the portion of the D-D section of FIG. 2, the interlayer insulating film 35 is etched to form contact holes 36 of a reverse circular truncated cone shape or a reverse elliptical truncated cone shape. In the contact holes 36, contact conductive films of a circular truncated cone shape or an elliptical truncated cone shape are filled. The contact conductive films are composed of a combination of polysilicon or tungsten (W) and a barrier metal such as titanium nitride (TiN), for example. With filling electrically conductive films, contacts 37 are formed to connect the active areas 56 to wiring layers formed in an upper layer of the interlayer insulating film 35 electrically. The contacts 37 constitute portions of the contact plugs 24ₐ, 24_{b} shown in FIG. 3.

A third interval W₃ is provided in the column direction between bottom portions of the contacts 37. The third interval W₃ is larger than the first interval W₁ and narrower than the second interval W₂. In this case, the width of parts of the bottom portions of the contacts 37 on the side of the active areas 56 is desirably wider in the column direction, in order to suppress electric resistance between the active areas 56 and the contacts 37. Thus, the positions of the contacts 37 in the column direction are extended from the tops of the active areas 56 to the tops of portions of the element isolation layers 26₂, respectively, in consideration of misalignment arising between the contacts 37 and the active areas 56 in manufacturing.

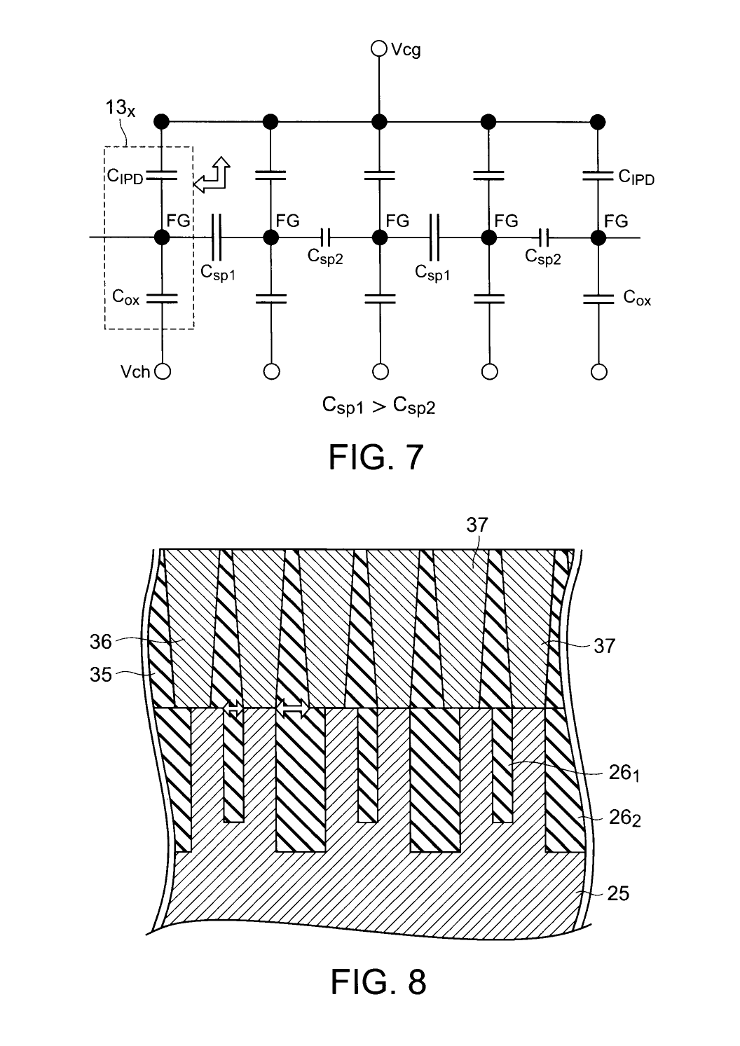

FIG. 7 shows a capacitance network to explain effects of the NAND flash memory according to the first embodiment. V_{cg} is a gate voltage to be applied to the control gates. V_{ch} is a voltage of the semiconductor substrate 25. C_{IPD} is a capacitance between each of the floating gates 22 and each of the control gates sandwiching the inter-gate insulating film 28. C_{OX} is a capacitance between each of the floating gates 22 and each of the channel portions of the semiconductor substrate 25 sandwiching the tunnel insulating film 27. C_{SP1} is a capacitance between the floating gates 22 adjacent to each other which sandwich each of the element isolation layers 26₁. C_{SP2} is a capacitance between the floating gate 22 adjacent to each other which sandwich each of the element isolation layer 26₂.

The coupling ratio is determined by the ratio of C_{IPD} to C_{OX}, when C_{SP1} and C_{SP2} are small enough to be disregard. Accordingly, it is effective to increase C_{IPD} in order to make the coupling ratio large.

In the NAND flash memory according to the first embodiment, some of the intervals of the memory cells are set to the second interval W₂ to ensure a large depth for filling the control gates. As a result, C_{IPD} can be made large even if the memory cell array 1 is miniaturized.

In the NAND flash memory according to the first embodiment, the others of the intervals of the memory cells, i.e. the intervals of the memory cell 13_{X} in FIG. 7, are set to the second interval W₂. Thus, the distance between the adjacent floating gates is made small so that C_{SP1} can be made larger than C_{SP2}. As a result, the coupling ratio can be made larger, from the effect of the series connection capacitance of the adjacent capacitors of C_{IPD} and C_{SP1} which is indicated by an arrow.

The tip shapes of the floating gates 22 are thin on the sides of the control gates so that the opposite areas between the floating gates 22 and the control gate portions of the word lines 16₀-16₆₅ increases and the coupling ratio can be larger. In addition, reduction of the coupling ratio due to depleting of the control gates can be suppressed. Each tip shape of the floating gates 22 can be made thin by etching an oxide film existing on each surface of the floating gates 22 under a wet atmosphere.

As shown in FIG. 8, even when the contacts 37 are provided in misalignment, the width of an contact area between each of the contacts 37 and each of the active areas adjacent to each other does not become smaller than the interval between the adjacent active areas or the interval between the adjacent contacts 37 (respectively shown by thick arrows), in the case that the amount of the misalignment is smaller than the size of the contacts 37 which are provided to extend to the side of the element isolation layers 26₂. Accordingly, lowering of the break down voltage of adjacent each of the contacts 37 and each of the active areas is suppressed.

According to the embodiment, since the heights of the element isolation layers 26₁ are higher than those of the element isolation layers 26₂ as shown in FIG. 4, failure of filling the word lines 16ₙ can be suppressed. Further, since the width of the element isolation layers 26₂ is larger than the average pitch of the memory cells 13ₙ, failure of filling the word lines 16ₙ and depleting of the same can be suppressed.

In the embodiment, silicidation of the surface portion of the semiconductor substrate 25 to be connected electrically to contacts 37 may be performed using Mo, W, Ti, Co, Ni etc. beforehand, when the contacts 37 are formed. Further, part of the surface portion of the semiconductor substrate 25 to be connected electrically to contacts 37 may be a cut shape in the case that a damascene process is employed to form the contacts 37.

Before the etching described above using FIG. 6H, the side wall films 33 may be covered with a mask, when the film thickness or the resistance to etching of the side wall films 33 are short. For the mask, a silicon oxide film or a silicon nitride film can be used.

In filling the insulating films of FIG. 6I, voids may be produced in the insulating films 26₁, 26₂. Especially, in the element isolation layers 26₁, voids can be formed easily because the layers have a narrow width.

According to the embodiment, in FIG. 2, the drains 23, 23ₐ₂, 23_{b1}, and the sources 23, 23ₐ₁, 23_{b2} are formed by implanting ions into semiconductor substrate 25, but the with ion-implantation may be omitted when the memory cells 13₀-13₆₅ are electrically connected with each other in series.

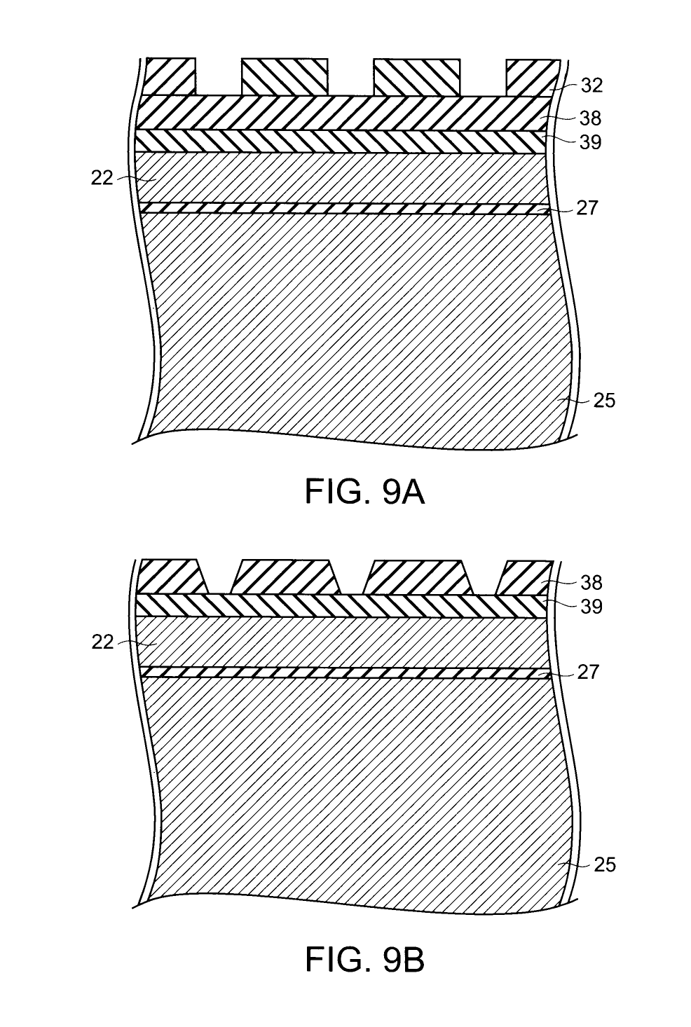

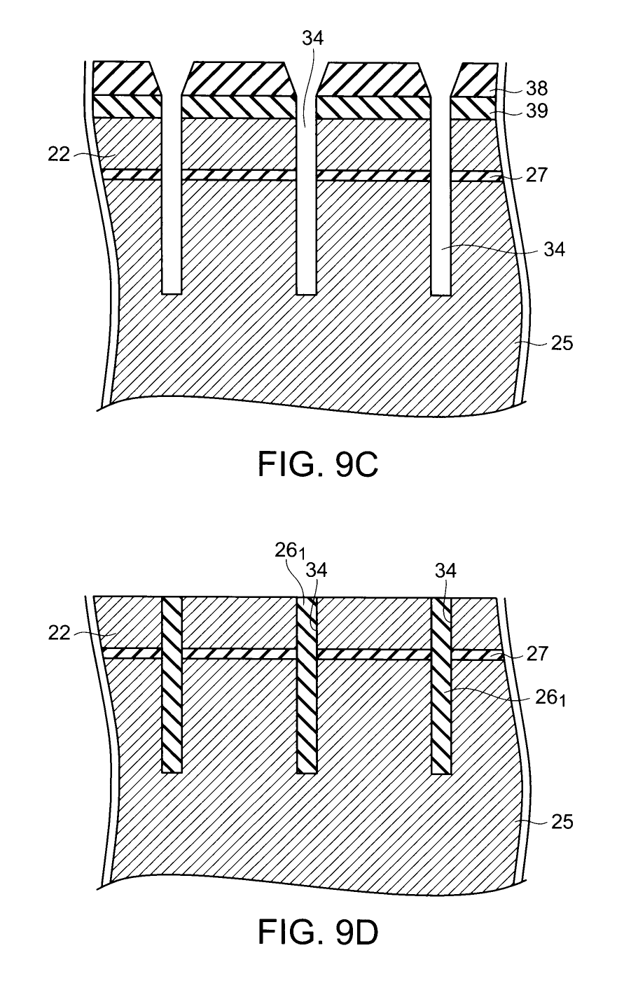

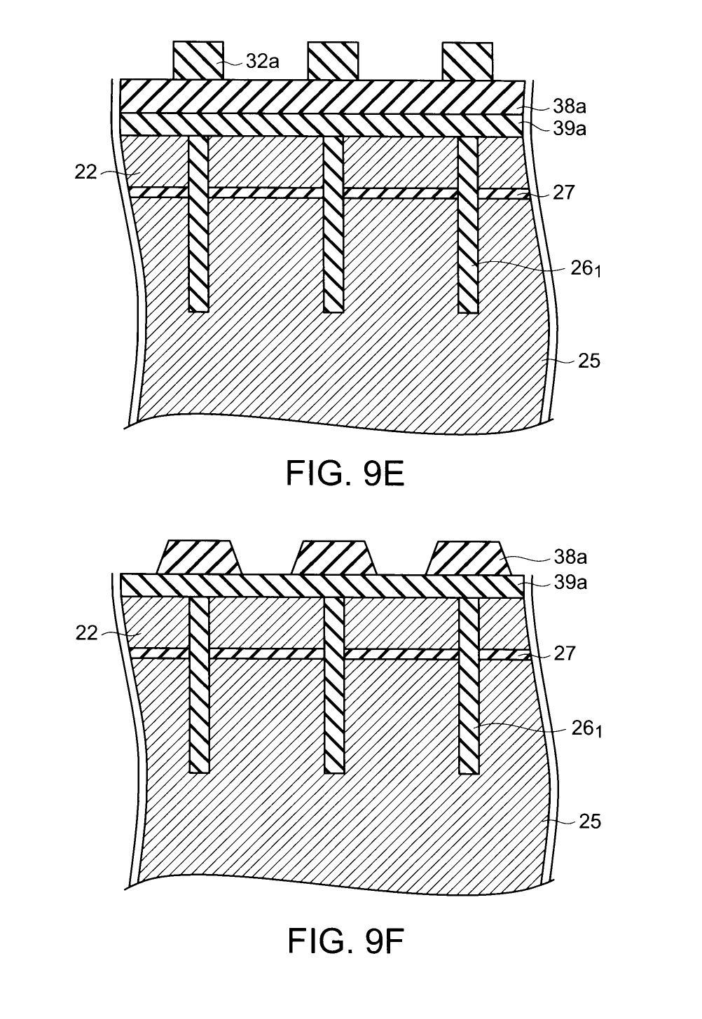

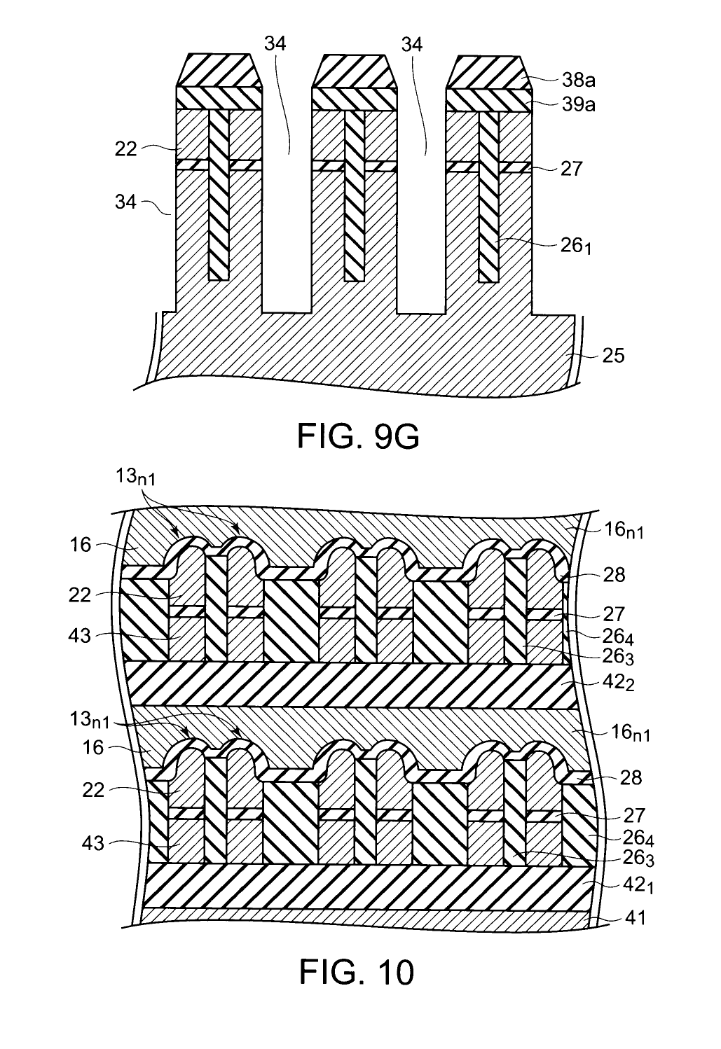

FIGS. 9A to 9G show steps of an example of a method of manufacturing a NAND flash memory according to a second embodiment. FIGS. 9A to 9G correspond to a portion of the B-B section of FIG. 2, respectively. The NAND flash memory of the second embodiment is not different from the first embodiment substantially in completed shape, but is different from the latter in that, in manufacturing, the number of times of exposure and development is increased by one and the side wall transfer process is not necessary to be used.

According to the example of the method of manufacturing the NAND flash memory according to the second embodiment, a tunnel insulating film 27 and a floating gate layer 22 are formed in the order on a P type semiconductor layer 25 formed in an N type semiconductor substrate, as the example of the method of manufacturing the NAND flash memory according to the first embodiment shown in FIG. 6A.

Then, as shown in FIG. 9A, mask materials 38, 39 are formed to provide element isolation layers 26₁ described below on the floating gate layer 22. For the mask materials 38, 39, a silicon oxide film or a silicon-nitride film which are formed using a CVD process can be employed. After forming the mask materials 38, 39, a resist pattern 32 is formed to pattern the mask material 38.

As shown in FIG. 9B, the mask material 38 is etched by using the resist pattern 32 as a mask, the resist pattern 32 is removed. For the etching, an anisotropic etching such as RIE can be used. By the etching, an etching shape of a taper is desirably formed so that the opening width of the mask material 38 may corresponds to the width of the element isolation layers 26₁ described above.

As shown in FIG. 9C, the mask material 39, the floating gate layer 22, the tunnel insulating film 27 and the semiconductor substrate 25 are etched in this order using the mask material 38 as a mask so that trenches 34 for forming element isolation layers are formed.

As shown in FIG. 9D, element isolation layers 26₁ are filled in the trenches 34. In order to fill the element isolation layers 26₁, an etching process such as a wet etching are performed to remove the mask materials 38, 39. After removal of the mask materials 38, 39, an insulating film is formed or applied to fill the element isolation layers 26₁ in the trenches 34. CVD or SOG can be used for the formation or application of the insulating film. After the element isolation layers 26₁ are filled, flattening is performed using CMP, for example.

Then, as shown in FIG. 9E, mask materials 38a, 39b are formed in order to provide element isolation layers 26₂ described below on the floating gate layer 22 and the flattened element isolation layers 26₁. After forming the mask materials 38a, 39b, a resist pattern 32a is formed to pattern the mask material 38a.

Further, as shown in FIG. 9F, the mask material 38a is etched by using the resist pattern 32a as a mask, and the resist pattern 32a is removed. The etching process is performed using an anisotropic etching such as RIE.

In this case, the mask material 38a is desirably etched to have a taper shape so that the opening width of the patterned mask material 38a may correspond to the width of the element isolation layers 26₂. The opening width of the mask material 38a is formed to correspond to the width of the element isolation layers 26₂ more easily when the angle of the taper is formed to be more closely perpendicular to the semiconductor substrate 25 than the mask material 38 shown in FIG. 9B.

As shown in FIG. 9G, the mask material 39a, the floating gate layer 22, the tunnel insulating film 27 and the semiconductor substrate 25 are etched in this order using the mask material 38a as a mask so that trenches 34 are formed to provide element isolation layers 26₂ described below.

Then, similarly to the step shown in FIG. 6I, the element isolation layers 26₂ are filled in the trenches 34. In order to fill the element isolation layers 26₂, the mask materials 38a, 39a are removed using an etching process such as a wet etching. After removal of the mask materials 38a, 39a, an insulating film is formed or applied to fill the element isolation layers 26₂. CVD or SOG can be used for the formation or application of the insulating film. After the element isolation layers 26₂ are filled, flattening is performed using CMP, for example.

Since the subsequent steps are similar to the step of FIG. 6J and the subsequent steps of the example of the method of manufacturing the NAND flash memory according to the first embodiment, the former subsequent steps will be omitted to be explained.

The NAND flash memory according to the second embodiment can make the capacitance C_{IPD} large even when the memory cell array 1 is miniaturized as in first embodiment. Further, the coupling ratio can be larger. Lowering of the breakdown voltages between the contacts 37 and the active areas adjacent to each other can be suppressed, and the failure of filling the word lines 16, and depleting of the same can be suppressed.

FIG. 10 shows a section of a NAND flash memory according to a third embodiment. FIG. 10 corresponds to the B-B section of FIG. 2.

The NAND flash memory of the third embodiment differs from the first and second embodiments mainly in that memory cells 13ₙ₁ composing a memory cell array are formed on a SOI (Silicon on Insulator) substrate and in that memory cells 13ₙ₁ are laminated. FIG. 10 shows a portion where two layers are laminated, for explanatory convenience.

In the first layer from the bottom, memory cells 13ₙ₁ are formed on an insulating layer 42₁ which is provided on a silicon substrate 41. In addition, a semiconductor layer 43 (a semiconductor region) is formed instead of the semiconductor substrate 25 employed in first and second embodiments. The element isolation layers 26₃, 26₄ are provided instead of the element isolation layers 26₁, 26₂.

A silicon wafer may be used for the semiconductor substrate 41. A silicon oxide film may be used for the insulating layer 42₁. A silicon layer formed by epitaxial growth or a polysilicon layer formed by CVD may be used for the semiconductor layer 43. The element isolation layers 26₃, 26₄ are same as those of the element isolation layers 26₁, 26₂ of the first and second embodiments, and 26₂ except for the point that the depth of the layers 26₃, 26₄ extends to a surface of the insulating layer 42₁. A word line 16ₙ₁ is formed on the insulating film 28.

In the second layer from the bottom and an upper layer formed above the second layer, memory cells 13ₙ₁ are formed on an insulating layer 42₂ which is formed to cover the word line 16ₙ₁. The other configurations of the second layer are same as those of the first layer.

In the NAND flash memory according to the third embodiment, similarly to the first and second embodiments, the capacitance C_{IPD} may be large, even the memory cell array is miniaturized. In addition, the coupling ratio may be larger. Lowering of break down voltage is suppressed between adjacent contact and an active area. Failure of filling the word lines 16ₙ₁ and depleting of the word lines 16ₙ₁ may be suppressed.

According to the embodiment, since the memory cells 13ₙ₁ are formed on the SOI, leak current may be reduced and the memory cells 13ₙ₁ may be easily formed in the laminated direction.

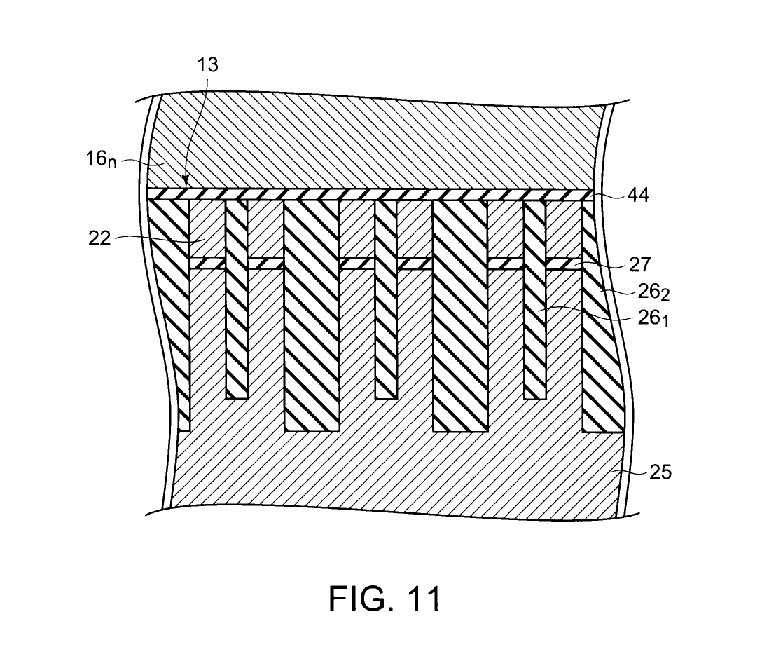

FIG. 11 shows a section of a NAND flash memory according to a fourth embodiment. The NAND flash memory has a memory cell array. FIG. 11 corresponds to the B-B section of FIG. 2.

The NAND flash memory of the fourth embodiment differs from the first to third embodiments mainly in that flat inter-gate insulating film 44 is used instead of the inter-gate insulating film 28 used in the former.

For the inter-gate insulating film 44, an insulating film having a higher dielectric constant, such as an aluminum oxide, may be used.

In the NAND flash memory according to the first to third embodiments, the element isolation layers 26₁, 26₂ are etched until the heights of the layers 26₁, 26₂ become lower than the floating gate 22, as shown in FIGS. 4, 6J and 10. In the fourth embodiment, the heights of the element isolation layers 26₁, 26₂ are almost same as the floating gate 22.

According to the embodiment, the insulating film having the higher dielectric constant is used for the inter-gate insulating film 44 so that a desirable coupling ratio may be obtained. Thus, the area where a portion of the control gate portion of the word line 16ₙ and the floating gate 22 faces each other may be small.

In the NAND flash memory according to the fourth embodiment, similarly to the first to third embodiments, the capacitance C_{IPD} may be large even if the memory cell array is miniaturized. In addition, the coupling ratio may be larger. Lowering of break down voltage is suppressed between adjacent contact and an active area. Failure of filling the word lines 16ₙ₁ and depleting of the word lines 16ₙ₁ may be suppressed.

The embodiments described above are NAND flash memories, but the embodiments are not limited to the NAND type.

In the manufacturing method of the NAND flash memory of the third embodiment mentioned above, the method of forming the SOI may be a SIMOX method or a wafer bonding method.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
memory cells formed on a semiconductor layer and arranged in matrix, each of the memory cells having a floating gate and a control gate, each plurality of the memory cells being connected in series in a row direction; and
word lines, each of the word lines being connected to each plurality of the control gates in a column direction,
wherein first and second intervals are provided for the memory cells alternately in the column direction, the second interval being larger than the first interval.

2. A device according to claim 1, further comprising:
selection gate transistors formed on the semiconductor layer, each of the selection gate transistors being respectively connected with series-connection ends of each plurality of the memory cell connected in series;
contacts formed on the semiconductor layer, each of the contacts being connected to each of the selection gate transistors, respectively;
bit lines extended in the row direction and connected to the contacts, respectively; and
an element isolation insulating layer formed between the memory cells, the element isolation insulating layer having element isolation layers provided alternately in a column direction,
wherein active regions are provided in the semiconductor layer, each of the active regions being provided between adjacent ones of the element isolation layers, and the contacts are connected to plural ones of the active regions.

3. A device according to claim 2, wherein the contacts have a third interval in the column direction, the third interval being larger than the first interval and narrower than the second interval.

4. A device according to claim 1, wherein, the element isolation layers include first element isolation layers providing the first interval respectively and second element isolation layers providing the second interval respectively, the first and second element isolation layers being arranged alternately in a column direction in the semiconductor layer.

5. A device according to claim 2, wherein at least one of two adjacent contacts of the contacts extends to a top surface of a portion of one of the element isolation regions from one of the active regions in a column direction.

6. A device according to claim 4, wherein the heights of the second element isolation layers are lower than those of the first element isolation layers.

7. A device according to claim 4, wherein the second element isolation layers are formed more deeply than the first element isolation layers.

8. A device according to claim 2, wherein, a source and a drain are formed in each of the active regions.

9. A device according to claim 1, wherein the semiconductor layer is formed in a surface region of a semiconductor substrate.

10. A device according to claim 1, wherein the semiconductor layer is formed on an insulating layer.

11. A method of manufacturing a semiconductor memory device, comprising:
forming a tunnel insulating layer, a floating gate layer, and a hard mask material layer on a semiconductor layer in the order;
removing the hard mask material layer selectively and forming a hard mask pattern;
forming a first insulating layer so as to cover the hard mask pattern,
etching the first insulating layer until the floating gate layer is exposed so as to leave a portion of the first insulating layer on a side wall of the hard mask pattern to form a side wall film having openings;
removing the hard mask pattern;
etching the floating gate layer, the tunnel insulating layer and at least a surface region of the semiconductor layer anisotropically in a depth direction of the semiconductor layer using the side wall film having the openings as a mask and forming first trenches and second trenches alternately in the semiconductor layer in the direction of a surface of the semiconductor layer, the first trenches having a width corresponding to each of the openings, the second trenches having a width different from that corresponding to each of the opening;
filling a second insulating material layer in the first and the second trenches so as to form first element isolation layers and second element isolation layers respectively;
forming an inter-gate insulating layer and a control gate layer for forming word lines in the order on the floating gate layer;
patterning the control gate layer, the inter-gate insulating layer and the floating gate layer so as to form control gates and floating gates;
forming an interlayer insulating film;
forming openings in the interlayer insulating film; and
filling an electro-conductive material in the openings of the interlayer insulating film so as to form contacts.

12. A method according to claim 11, wherein the width of each of the second trenches is formed to be larger than that of each of the first trenches.

13. A method according to claim 11, wherein sources and drains are formed in the surface region of the semiconductor layer after forming the control gates and the floating gates before forming the interlayer insulating film.

14. A method according to claim 11, wherein the heights of the second element isolation layers are lower than those of the first element isolation layers.

15. A method of manufacturing a semiconductor memory device, comprising:
forming a tunnel insulating layer, a floating gate layer and a first mask material layer on a semiconductor layer in the order;
patterning the first mask material layer to form a first mask pattern;
etching the floating gate layer, the tunnel insulating layer and at least a surface region of the semiconductor layer anisotropically in a depth direction of the semiconductor layer using the first mask pattern so as to form first trenches;
forming first trenches and second trenches alternately in the semiconductor layer in the direction of a surface of the semiconductor layer, the first trenches having a width corresponding to each of the openings, the second trenches having a width different from that corresponding to each of the opening;
filling an insulating layer in the first trenches so as to form first element isolation layers respectively;
removing the first mask pattern;
forming a second mask material layer on the floating gate layer;
patterning the second mask material layer to form a second mask pattern;
etching the floating gate layer, the tunnel insulating layer and at least a surface region of the semiconductor layer anisotropically in a depth direction of the semiconductor layer using the second mask pattern as a mask so as to form second trenches having a width different from that of the first trenches;
filling an insulating layer in the second trenches so that second element isolation layers may be formed respectively;
removing the second mask pattern;
forming an inter-gate insulating layer and a control gate layer for forming word lines in the order on the floating gate layer;
patterning the control gate layer, the inter-gate insulating layer and the floating gate layer so as to form control gates and floating gates;
forming an interlayer insulating film;
forming openings in the interlayer insulating film; and
filling an electro-conductive material in the openings of the interlayer insulating film so as to form contacts.

16. A method according to claim 15, wherein the width of each of the second trenches is formed to be larger than that of each of the first trenches.

17. A method according to claim 16, wherein sources and drains are formed in the surface region of the semiconductor layer after forming the control gates and the floating gates before forming the interlayer insulating film.

18. A method according to claim 16, wherein the heights of the second element isolation layers are lower than those of the first element isolation layers.
